(19) United States
(12) Patent Application Publication
(10) Pub. No.: US 2025/0357724 A1
(43) Pub. Date: Nov. 20, 2025

(54) OPTICAL PACKAGE AND METHOD OF MANUFACTURE

(71) Applicant: Taiwan Semiconductor Manufacturing Co., Ltd., Hsinchu (TW)

(72) Inventors: Chen-Hua Yu, Hsinchu (TW); Yu-Hung Lin, Taichung City (TW); Ren-Fen Tsui, Taipei (TW)

(21) Appl. No.: 19/284,117

(22) Filed: Jul. 29, 2025

Related U.S. Application Data
(63) Continuation of application No. 18/663,551, filed on May 14, 2024.
(60) Provisional application No. 63/563,500, filed on Mar. 11, 2024.

(51) Int. Cl. H01S 5/042; H01S 5/323

(52) U.S. Cl. CPC H01S 5/04252; H01S 5/04254; H01S 5/04256; H01S 5/32391

(57) ABSTRACT

A method includes forming a laser diode structure including an active layer sandwiched between an n-type contact layer and a p-type contact layer; forming an n-type contact on the n-type contact layer, wherein the n-type contact includes a first noble metal; forming a p-type contact on the p-type contact layer, wherein the p-type contact includes a second noble metal; forming a conductive routing layer on the n-type contact and on the p-type contact, wherein the conductive routing layer is free of noble metals, wherein the conductive routing layer fully covers the n-type contact and the p-type contact; and forming a passivation layer over the conductive routing layer.

### PRIORITY CLAIM AND CROSS-REFERENCE

This application is a continuation of U.S. patent application Ser. No. 18/663,551, filed on May 14, 2024, which claims the benefit of U.S. Provisional Application No. 63/563,500, filed on Mar. 11, 2024, each application is hereby incorporated herein by reference.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, and 10 illustrate cross-sectional views of intermediate steps in the formation of a laser die, in accordance with some embodiments.

FIG. 11 illustrates a cross-sectional view of an intermediate step in the formation of a laser die, in accordance with some embodiments.

FIGS. 12, 13, 14, 15, and 16 illustrate cross-sectional views of intermediate steps in the formation of a laser die, in accordance with some embodiments.

FIGS. 17 and 18 illustrate cross-sectional views of intermediate steps in the formation of an interposer structure, in accordance with some embodiments.

FIGS. 19, 20, 21, and 22 illustrate cross-sectional views of intermediate steps in the formation of a package, in accordance with some embodiments.

FIGS. 23, 24, 25, and 26 illustrate cross-sectional views of intermediate steps in the formation of a package, in accordance with some embodiments.

FIGS. 27, 28, and 29 illustrate cross-sectional views of package structures, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which one or more laser dies and semiconductor dies are bonded to an optical interposer to form a package. The laser dies are manufactured with processes that allow for the utilization of noble metals (e.g., gold) or other materials that may be incompatible with other semiconductor fabrication processes. For example, the laser dies described herein utilize noble metals for electrical contacts and utilize more compatible metals for overlying electrical routing. In this manner, contamination from noble metals can be avoided while allowing for the benefits provided by the use of noble metals in electrical contacts. However, the embodiments presented herein are intended to be illustrative and are not intended to limit the embodiments to the precise descriptions as discussed. Rather, the embodiments discussed may be incorporated into a wide variety of implementations, and all such implementations are fully intended to be included within the scope of the embodiments.

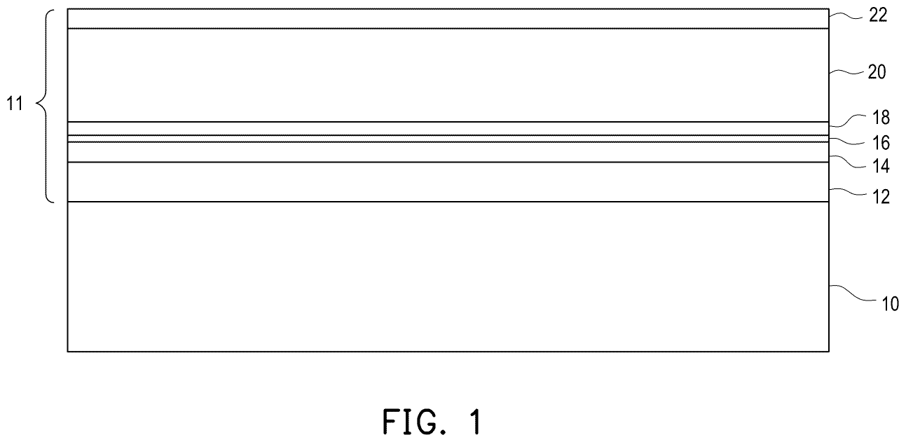

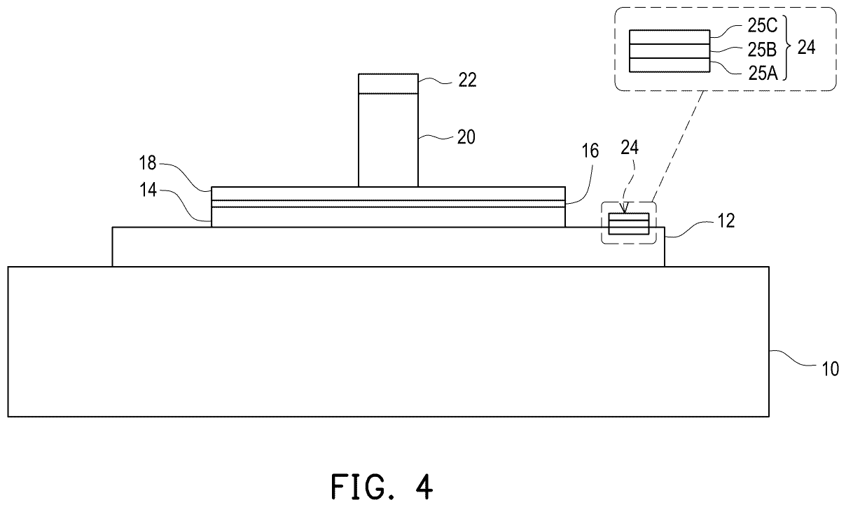

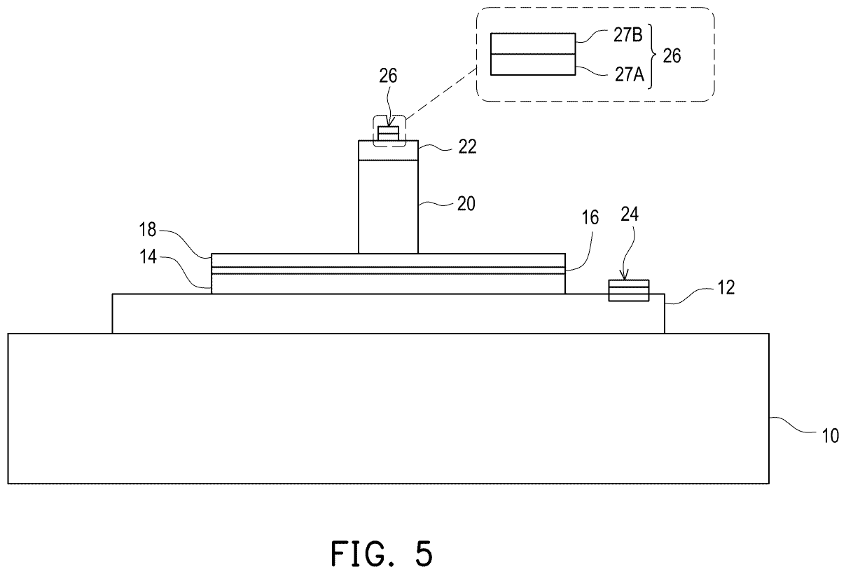

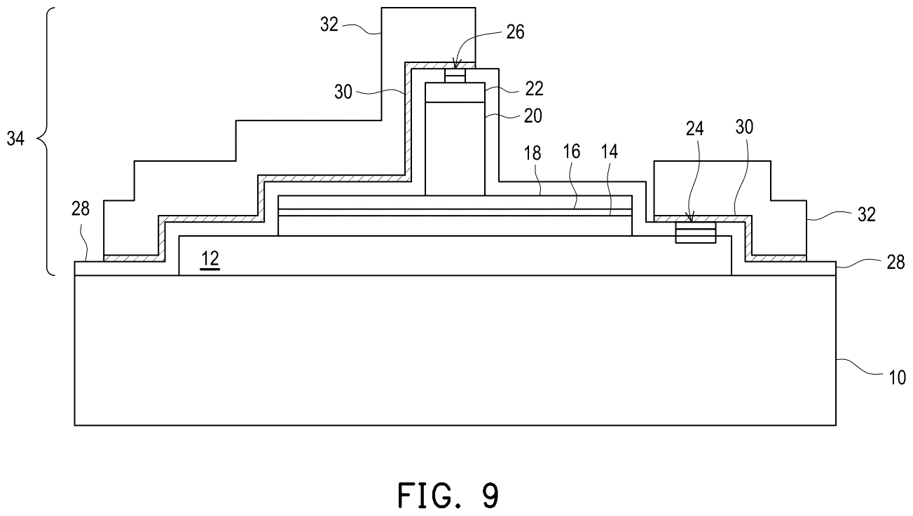

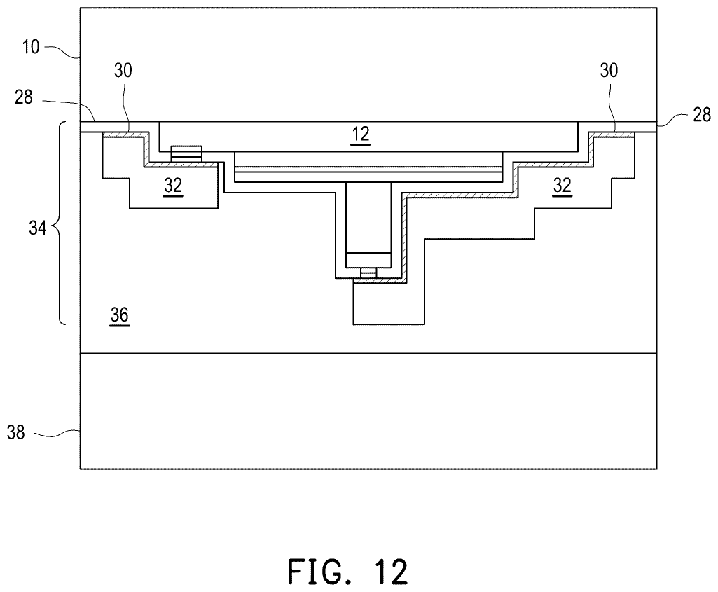

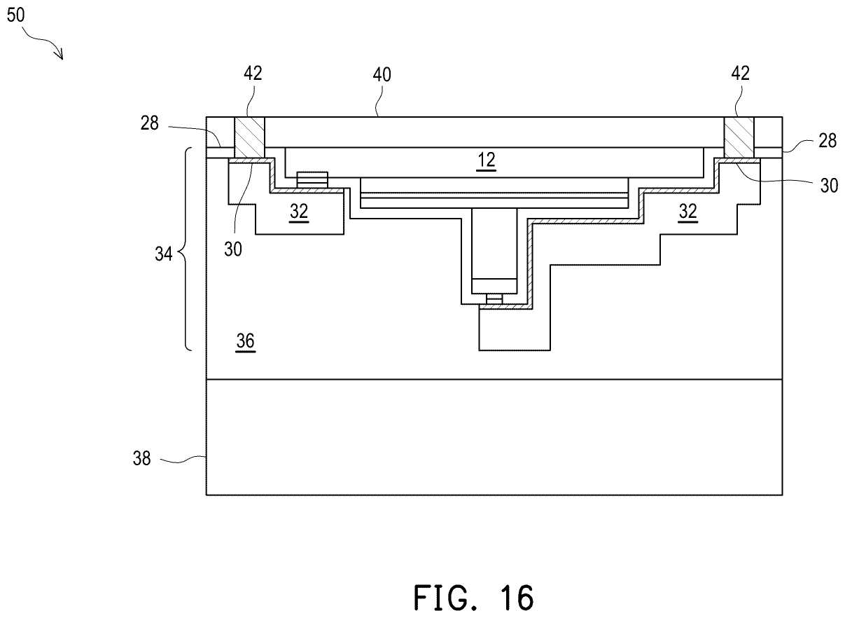

FIGS. 1 through 16 illustrate intermediate steps in the formation of a laser die 50 (see FIG. 16), in accordance with some embodiments. The laser die 50 is utilized to provide optical power (e.g., light) to optical components, photonic components, waveguides, or the like within a package. The laser die 50 may comprise light-generating structures such as the laser diode 34 described below for FIG. 9. In particular embodiments the laser diode 34 may comprise a Fabry-Perot Diode, and may be based on III-V materials, II-VI materials, or any other suitable set of materials. The laser die 50 may have another configuration than shown, and may be formed using other materials or techniques than described for FIGS. 1-16. For example, the embodiment described for FIGS. 1-16 includes an n-type first contact layer 12 with a corresponding n-type contact 24 (see FIG. 4) and a p-type second contact layer 22 with a corresponding p-type contact 26 (see FIG. 5), but in other embodiments, the first contact layer 12 may be p-type with a corresponding p-type contact and the second contact layer 22 may be n-type with a corresponding n-type contact. Other configurations are possible. In some embodiments, multiple laser dies 50 are formed on the same substrate 10 (see FIG. 1) and/or the same support substrate 38 (see FIG. 12) and then singulated into individual laser dies 50.

FIG. 1 illustrates a stack 11 of material layers on a substrate 10, in accordance with some embodiments. The stack 11 is subsequently patterned as part of forming the laser die 50, in accordance with some embodiments. In some embodiments, the stack 11 comprises a first contact layer 12, a first buffer layer 14, an active layer 16 comprising multiple quantum wells (MQW), a second buffer layer 18, a cladding layer 20, and a second contact layer 22. In other embodiments, other layers may be present in the stack 11, or the layers of the stack 11 may have different characteristics than described herein. As an example, in other embodiments, an etch stop layer and/or a release layer may be present between the substrate 10 and the n-type contact layer 12. The layers of the stack 11 may be formed using suitable techniques, such as using epitaxial growth processes or the like.

In some embodiments, the substrate 10 can provide structural support and act as a seed surface for epitaxially growing the overlying materials of the stack 11. In some embodiments, the substrate 10 may be, for example, a 2-inch wafer, a 4-inch wafer, or the like. In particular embodiments in which the laser die 50 utilizes III-V materials to form the desired lasers, the substrate 10 may be a material such as indium phosphide, gallium arsenide, or gallium antimony. In other embodiments in which the laser die 50 utilizes II-VI materials to form the desired lasers, the substrate 10 may be a material such as gallium arsenide, cadmium telluride, zinc selenide, or the like. In still further embodiments, the substrate 10 may be a sapphire material, a semiconductor material, or a stack of multiple materials. All suitable materials may be utilized.

The first contact layer 12 is formed over the substrate 10. The first contact layer 12 is subsequently patterned to form a first contact layer 12 of the laser diode 34. For embodiments in which the laser diode 34 utilizes III-V compounds, the first contact layer 12 may comprise a material such as indium phosphide, gallium nitride, indium nitride, aluminum nitride, aluminum gallium nitride, aluminum indium nitride, aluminum indium gallium nitride, combinations thereof, or the like. Additionally, for embodiments in which the laser diode 34 utilizes II-VI compounds, the first contact layer 12 may use a III-V material such as indium phosphide, gallium arsenide, gallium antimonide, combinations of these, or the like. Other materials are possible.

In some embodiments, the first contact layer 12 may be doped with one or more dopants. For embodiments in which the first contact layer 12 is an n-type first contact layer 12, the first contact layer 12 may be doped with one or more n-type dopants such as phosphorus, arsenic, antimony, bismuth, lithium, combinations thereof, or the like. In other embodiments in which the first contact layer 12 is a p-type first contact layer 12, the first contact layer 12 may be doped with one or more p-type dopants such as boron, aluminum, gallium, indium, combinations thereof, or the like. However, any suitable dopants may be utilized. In some embodiments the first contact layer 12 is formed, for example, using an epitaxial growth process such as molecular beam epitaxy (MBE), hydride vapor phase epitaxy (HVPE), liquid phase epitaxy (LPE), or the like. The first contact layer 12 may be doped in situ during formation, although other processes may be utilized, such as ion implantation, diffusion, or the like.

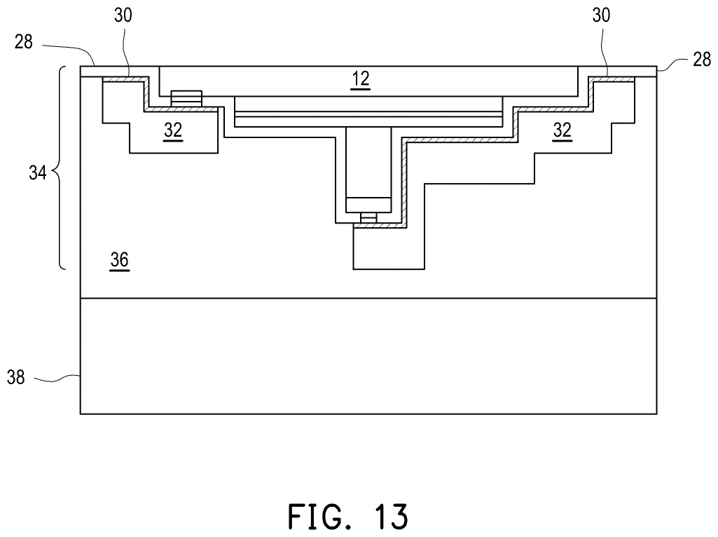

In some embodiments, an optional etch stop layer or release layer (not pictured) may be formed between the substrate 10 and the first contact layer 12. The etch stop layer or release layer may facilitate removal of the substrate 10 during subsequent processing steps (see FIG. 13). The etch stop layer or release layer may comprise a suitable material, such as indium gallium arsenide, indium aluminum arsenide, doped indium phosphide, another material, a combination thereof, or the like.

The first buffer layer 14 is formed over the first contact layer 12 and is utilized in order to facilitate transition from the material of the first contact layer 12 to the material of the overlying layer (e.g., the active layer 16), which can improve epitaxial growth of the overlying layers. In embodiments in which the laser diode 34 utilizes III-V compounds, the first buffer layer 14 may be a compound material such as indium gallium arsenide phosphide, indium gallium aluminum arsenide, indium gallium arsenide, combinations thereof, or the like. Additionally, in embodiments in which the laser diode 34 utilizes II-VI compounds, the first buffer layer 605 may be a II-VI material such as BeMgZnSe, BeZnCdSe, beryllium telluride, combinations of these, or the like. Additionally, the first buffer layer 14 may be deposited using an epitaxial growth process such as MBE, HVPE, LPE, or the like, and may be doped to the same type (e.g., n-type or p-type) as the first contact layer 12. The first buffer layer 14 may be doped using similar dopants or techniques as the first contact layer 12. However, any suitable material and any suitable method of deposition may be utilized.

The active layer 16 is formed over the first buffer layer 14. The active layer 16 may be configured or designed to control the generation of light of desired wavelengths. For example, by adjusting and controlling the proportional composition of the elements in the active layer 16, the bandgap of the materials in the active layer 16 may be adjusted, thereby adjusting the wavelength of light that will eventually be emitted.

In some embodiments, the active layer 16 comprises multiple quantum wells (MQW). MQW structures in the active layer 16 for embodiments which utilize III-V materials may comprise, for example, layers of indium aluminum gallium arsenide, indium gallium nitride, gallium nitride, aluminum indium gallium nitride, or the like. For embodiments which utilize II-VI based materials, the active layer 16 may comprise materials such as BeZnCdSe or the like. The active layer 16 may comprise any number of quantum wells, such as 5 to 20 quantum wells, for example, though other numbers of quantum wells are possible. In some embodiments, the active layer 16 may be epitaxially grown using metal organic chemical vapor deposition (MOCVD) with the first buffer layer 14 acting as a nucleation layer. Other processes, such as MBE, HVPE, LPE, or the like, may also be utilized.

The second buffer layer 18 is formed over the active layer 16 and is utilized in order to facilitate transition from the material of the active layer 16 to the material of the overlying layer (e.g., the cladding layer 20), which can improve epitaxial growth of the overlying layers. In an embodiment in which the laser diode 34 utilizes III-V compounds, the second buffer layer 18 is a compound material such as indium gallium arsenide phosphide, indium gallium aluminum arsenide, indium gallium arsenide, combinations thereof, or the like. Additionally, in embodiments in which the laser diode 34 utilizes II-VI compounds, the second buffer layer 18 may be a II-VI material such as BeMgZnSe, BeZnCdSe, beryllium telluride, combinations of these, or the like. Additionally, the second buffer layer 18 may be deposited using an epitaxial growth process such as MBE, HVPE, LPE, or the like, and may be doped to the opposite type (e.g., n-type or p-type) as the first contact layer 12. For example, the second buffer layer 18 may be doped as p-type when the first contact layer 12 is doped as n-type. However, any suitable material and any suitable method of deposition may be utilized.

The cladding layer 20 is formed over the second buffer layer 18, and may facilitate transition from the material of the second buffer layer 18 to the material of the overlying layer (e.g., the second contact layer 22), which can improve epitaxial growth of the overlying layers. The cladding layer 20 may facilitate optical confinement of the light generated in the active layer 16, and may be considered a “ridge layer” in some cases. In an embodiment in which the laser diode 34 utilizes III-V compounds, the cladding layer 20 is a compound material such as indium phosphide or the like. Additionally, in embodiments in which the laser diode 34 utilizes II-VI compounds, the cladding layer 20 may be a II-VI material such as BeMgZnSe, BeZnCdSe, beryllium telluride, combinations of these, or the like. Additionally, the cladding layer 20 may be deposited using an epitaxial growth process such as MBE, HVPE, LPE, or the like, and may be doped to the opposite type (e.g., n-type or p-type) as the first contact layer 12. For example, the cladding layer 20 may be doped as p-type when the first contact layer 12 is doped as n-type. However, any suitable material and any suitable method of deposition may be utilized.

The second contact layer 22 is formed over the cladding layer 20. The second contact layer 22 is subsequently patterned to form a second contact layer 22 of the laser diode 34. In an embodiment in which the laser diode 34 is based on III-V materials, the second contact layer 22 may comprise a group III-V compound material such as indium gallium arsenide, indium aluminum arsenide, gallium nitride, indium nitride, aluminum nitride, aluminum gallium nitride, aluminum indium nitride, aluminum indium gallium nitride, combinations thereof, or the like. Additionally, the second contact layer 22 may be deposited using an epitaxial growth process such as MBE, HVPE, LPE, or the like, and may be doped to the opposite type (e.g., n-type or p-type) as the first contact layer 12. For example, the cladding layer 20 may be doped as p-type when the first contact layer 12 is doped as n-type. In some embodiments, the second contact layer 22 may be doped with one or more p-type dopants such as boron, aluminum, gallium, indium, combinations thereof, or the like. However, any suitable material and any suitable methods of deposition or doping may be utilized.

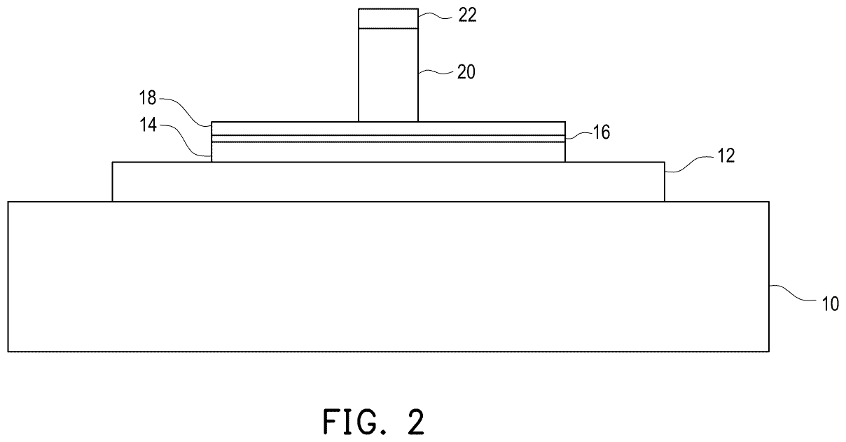

In FIG. 2, the stack 11 is patterned to form a laser diode structure, in accordance with some embodiments. The stack 11 may be patterned using suitable photolithographic masking and etching processes. Each etching process may include one or more wet etches and/or dry etches. In some embodiments, the second contact layer 22 and the cladding layer 20 are patterned using a first photolithographic masking and etching process. The second buffer layer 18, the active layer 16, and the first buffer layer 14 are patterned using a second photolithographic masking and etching process. The first contact layer 12 is patterned using a third photolithographic masking and etching process. For example, the first contact layer 12 is patterned to become a first contact layer 12. In some embodiments, the first contact layer 12 may have an adiabatic taper or other shape that facilitates evanescent optical coupling to underlying layers, structures, or waveguides. However, any suitable patterning processes and/or any suitable number of patterning processes may be utilized to pattern the stack 11 in other embodiments.

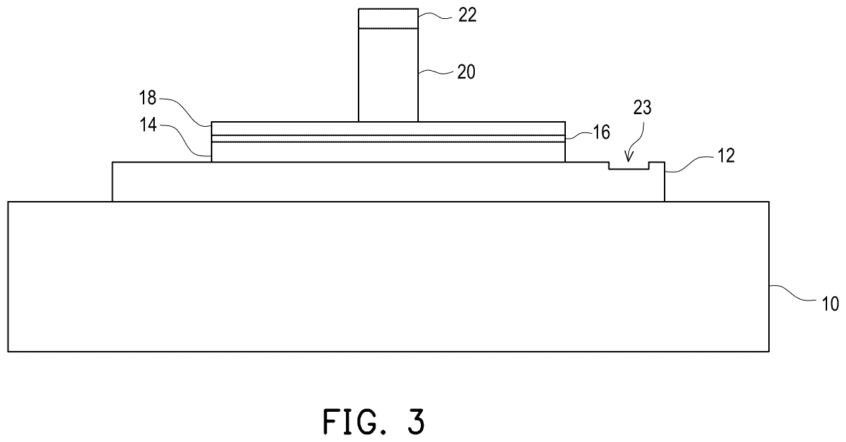

In FIG. 3, a recess 23 is formed in a top surface of the first contact layer 12, in accordance with some embodiments. An n-type contact 24 (see FIG. 4) is subsequently formed in the recess 23. The recessed surfaces of the first contact layer 12 within the recess 23 may also be referred to as the “contact area 23” of the first contact layer 12. In this manner, the contact area 23 of the first contact layer 12 is recessed from the top surface of the first contact layer 12. Forming a recess 23 as described herein may allow for improved physical isolation and reduced contact resistance of the subsequently formed n-type contact 24. The recess 23 may be formed using a suitable photolithographic masking and etching process. For example, a mask (e.g. a photoresist, hardmask, or the like) may be formed over the structure and patterned using photolithographic techniques, in which the pattern corresponds to the recess 23. The first contact layer 12 may then be etched using the patterned mask as an etch mask to form the recess 23. The etching may include one or more wet etching processes and/or dry etching processes. In some embodiments, the patterned mask is removed after forming the recess 23, and in other embodiments, the patterned mask is left remaining for use during formation of the n-contact 24, described below. In some embodiments, the recess 23 has a depth (e.g., from a top surface of the first contact layer 12) that is in the range of about 0.01 μm to about 0.5 μm. In some embodiments, the recess 23 has a length or width that is in the range of about 50 μm to about 2000 μm. Other dimensions are possible.

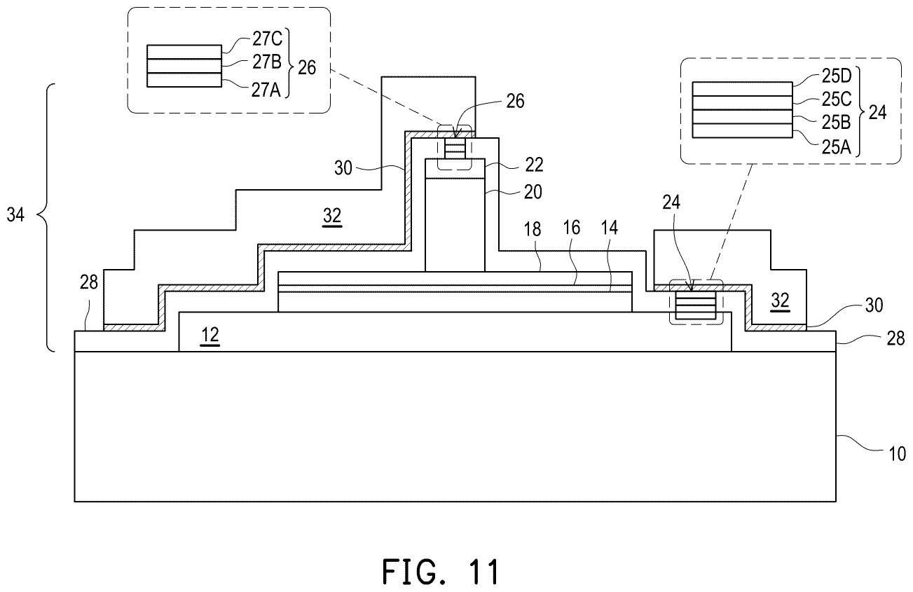

In FIG. 4, one or more conductive layers 25 are deposited in the recess 23 to form the n-type contact 24, in accordance with some embodiments. For example, the n-type contact 24 shown in FIG. 4 includes three conductive layers 25, indicated as bottom conductive layer 25A, middle conductive layer 25B, and top conductive layer 25C. In other embodiments, an n-type contact 24 may have only one conductive layer 25, two conductive layers 25, or more than three conductive layers 25. An example of an n-type contact 24 comprising four conductive layers 25A-D is described below for FIG. 11. The conductive layers 25 may comprise one or more conductive materials such as gold, germanium, nickel, titanium, other metals, alloys thereof, combinations thereof, or the like. The conductive layers 25 of an n-type contact 24 may be formed of different materials, the arrangement of which may be chosen to provide desired properties. For example, with reference to FIG. 4, the bottom conductive layer 25A may be gold, the middle conductive layer 25B may be germanium, and the top conductive layer 25C may be nickel. This is an example, and other materials or combinations of materials are possible. The conductive layers 25 of the n-type contact 24 may be deposited using one or more suitable deposition techniques, such as chemical vapor deposition (CVD), physical vapor deposition (PVD), atomic layer deposition (ALD), plating, or the like.

In some embodiments, a mask may be formed over the laser diode structure and patterned (e.g., using photolithographic techniques) to expose the contact area 23. The materials of the conductive layers 25 may be deposited over the patterned mask and over the contact area 23. The patterned mask may then be removed, leaving the n-type contact 24 formed on the contact area 23. In other embodiments, the patterned mask used to form the recess 23 may be left remaining over the structure and used during deposition of the conductive layers 25. In some embodiments, the n-type contact 24 is formed only within or over the recess 23. In other words, the n-type contact 24 is formed only on the contact area 23 of the first contact layer 12. Accordingly, the entire n-type contact 24 is inside the perimeter of the first contact layer 12, and the entire n-type contact 24 laterally overlaps the first contact layer 12. In some embodiments, the n-type contact 24 does not extend on or over the top surface of the first contact layer 12. In some embodiments, entire bottom surface of the n-type contact 24 physically contacts a surface of the first contact layer 12. Forming the n-type contact 24 in the recess 23 (e.g., only on the contact area 23) may allow for improved contact quality and improved physical isolation that can reduce contamination, described in greater detail below.

In some embodiments, each conductive layer 25 of the n-type contact 24 may have a thickness in the range of about 10 nm to about 500 nm, and the n-type contact 24 may have an overall thickness in the range of about 30 nm to about 1.5 μm. Other thicknesses are possible. A thickness of a conductive layer 25 or the overall thickness of the n-type contact 24 may be greater than, less than, or about the same as the depth of the recess 23. The top surface of the n-type contact 24 may be lower than, approximately level with, or protrude from the top surface of the first contact layer 12. For example, FIG. 4 shows the n-type contact 24 protruding from the top surface of the first contact layer 12.

In some embodiments, one or more conductive layers 25 of the n-type contact 24 may be fully or partially within the recess 23, and may or may not have exposed surfaces. For example, the bottom conductive layer 25A shown in FIG. 4 is fully within the recess 23 such that surfaces of the bottom conductive layer 25A are fully covered by the first contact layer 12 and the middle conductive layer 24B. In other embodiments, more than one conductive layer 25 may be fully within the recess 23. In some cases, fully covering a conductive layer 25 can reduce the chance of contamination. For example, covering a conductive layer 25 may reduce contamination by the material of the conductive layer 25 during subsequent processing. In some cases, materials such as noble metals can cause process defects or material defects during processing, and covering such a conductive layer 25 material can reduce the chance of defects due to contamination.

In FIG. 5, one or more conductive layers 27 are deposited on the second contact layer 22 to form the p-type contact 26, in accordance with some embodiments. For example, the p-type contact 26 shown in FIG. 5 includes two conductive layers 27, indicated as bottom conductive layer 27A and top conductive layer 27B. In other embodiments, a p-type contact 26 may have only one conductive layer 27 or more than two conductive layers 27. An example of a p-type contact 26 comprising three conductive layers 27A-C is described below for FIG. 11. The conductive layers 27 may comprise one or more conductive materials such as platinum, titanium, nickel, palladium, silver, gold, other metals, alloys thereof, combinations thereof, or the like. The conductive layers 27 of a p-type contact 26 may be formed of different materials, the arrangement of which may be chosen to provide desired properties. For example, with reference to FIG. 5, the bottom conductive layer 27A may be titanium and the top conductive layer 27B may be platinum. This is an example, and other materials or combinations of materials are possible. The conductive layers 27 of the p-type contact 26 may be deposited using one or more suitable deposition techniques, such as CVD, PVD, ALD, plating, or the like.

In some embodiments, a mask may be formed over the structure and patterned (e.g., using photolithographic techniques) to expose the second contact layer 22. The materials of the conductive layers 27 may be deposited over the patterned mask and over the second contact layer 22. The patterned mask may then be removed, leaving the p-type contact 26 formed on the second contact layer 22. In some embodiments, the p-type contact 26 is formed only on the second contact layer 22. As shown in FIG. 5, a width of the p-type contact 26 may be smaller than a width of the second contact layer 22. Accordingly, the entire p-type contact 26 is inside the perimeter of the second contact layer 22, and the entire p-type contact 26 laterally overlaps the second contact layer 22. In some embodiments, entire bottom surface of the p-type contact 26 physically contacts a surface of the second contact layer 22. In some embodiments, each conductive layer 27 of p-type contact 26 may have a thickness in the range of about 10 nm to about 500 nm, and the p-type contact 26 may have an overall thickness in the range of about 30 nm to about 1.5 μm. Other thicknesses are possible.

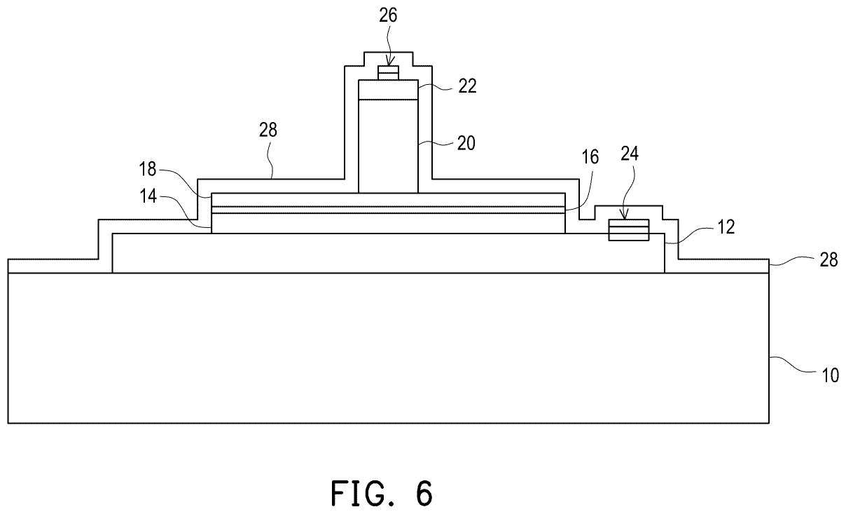

In FIG. 6, an insulating layer 28 is formed over the structure, in accordance with some embodiments. The insulating layer 28 protects and electrically isolates the first contact layer 12, the n-type contact 24, the first buffer layer 14, the active layer 16, the second buffer layer 18, the cladding layer 20, the second contact layer 22, and the p-type contact 26. Accordingly, the insulating layer 28 may comprise one or more insulating materials such as silicon oxide, silicon nitride, silicon oxynitride, the like, or a combination thereof. The insulating layer 28 may be deposited using a suitable technique such as CVD, ALD, PVD, the like, or a combination thereof. In some embodiments, the insulating layer 28 may be conformally deposited in a blanket layer. However, any suitable materials and any suitable methods of deposition may be utilized. In some embodiments, the insulating layer 28 has a thickness in the range of about 0.1 μm to about 5 μm, though other thicknesses are possible.

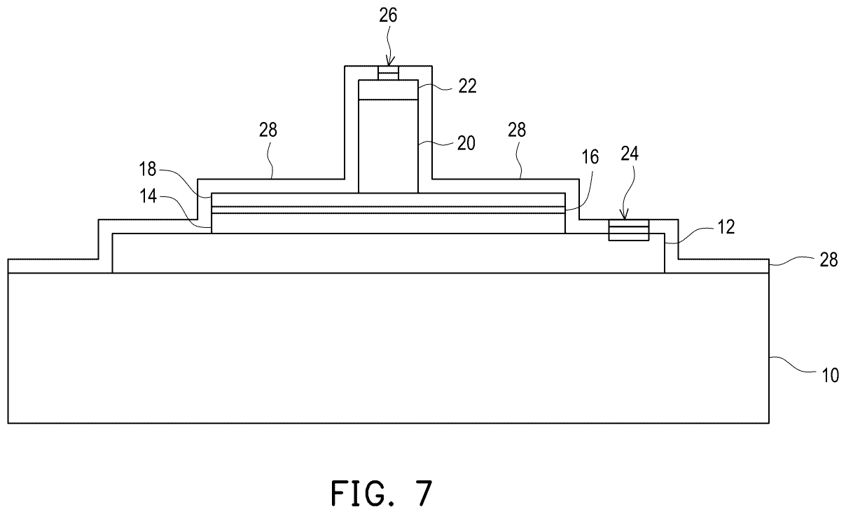

In FIG. 7, the insulating layer 28 is patterned to expose the n-type contact 24 and the p-type contact 26, in accordance with some embodiments. The patterning of the insulating layer 28 may form openings in the insulating layer 28 that expose the n-type contact 24 and the p-type contact 26. In other cases, the patterning of the insulating layer 28 may remove portions of the insulating layer 28 overlying the n-type contact 24 and the p-type contact 26. In some embodiments, the patterning exposes top surfaces of the n-type contact 24 and the p-type contact 26. In an embodiment the patterning may be performed using, e.g., a photolithographic masking and etching process. However, any suitable patterning process may be utilized. In some embodiments, top surfaces of the n-type contact 24 and/or the p-type contact 26 may be approximately level with corresponding top surfaces of the insulating layer 28. In other embodiments, top surfaces of the n-type contact 24 and/or the p-type contact 26 may be recessed from or protrude from corresponding top surfaces of the insulating layer 28.

In other embodiments, the insulating layer 28 is deposited before forming the n-type contact 24 and the p-type contact 26. One or more openings in the insulating layer 28 may then be patterned to expose the contact areas of the first contact layer 12 and the second contact layer 22. The conductive layers 25 of the n-type contact 24 and the conductive layers 27 of the p-type contact 26 may then be deposited through the opening(s) in the insulating layer 28. In some embodiments, a mask (e.g., a photoresist) may be deposited over the insulating layer 28 and patterned to expose the opening(s) in the insulating layer 28, thus exposing the first contact layer 12 and/or the second contact layer 22. The conductive layers 25 and/or the conductive layers 27 may be deposited over the mask and in the opening(s). The mask may then be removed, with the remaining portions of the conductive layers 25 and/or the conductive layers 27 forming the n-type contact 24 and/or the p-type contact 26. Separate patterned masks may be used to form the n-type contact 24 and the p-type contact 26, in some embodiments. This is an example, and other processes to form the n-type contact 24 and the p-type contact 26 are possible.

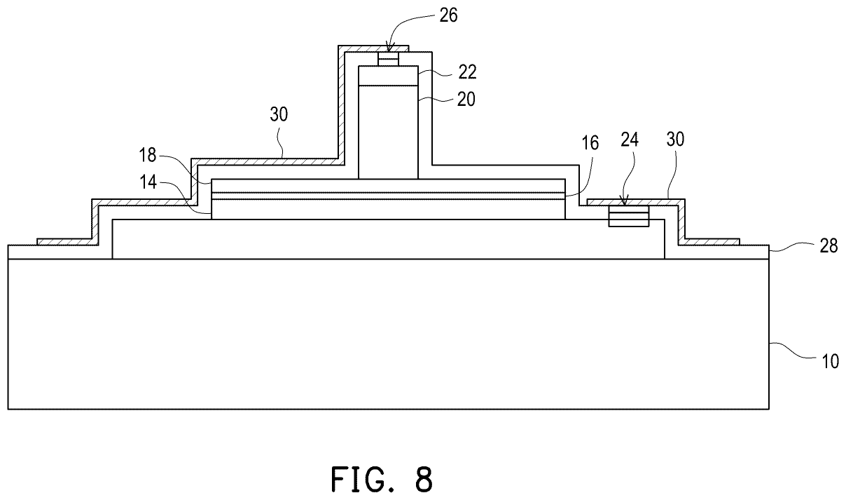

In FIG. 8, an adhesion layer 30 is deposited over the exposed surfaces of the n-type contact 24 and the p-type contact 26, in accordance with some embodiments. The adhesion layer 30 may facilitate adhesion of the overlying routing layers 32 (see FIG. 9) and protect the contacts 24/26, in accordance with some embodiments. The adhesion layer 30 makes physical and electrical contact to the n-type contact 24 and the p-type contact 26. For example, one region of the adhesion layer 30 is formed on the n-type contact 24 and another region of the adhesion layer 30 is formed on the p-type contact 26. As shown in FIG. 8, the adhesion layer 30 may also extend on surfaces of the insulating layer 28. The adhesion layer 30 may comprise one or more suitable conductive materials such as titanium, titanium nitride, tantalum, tantalum nitride, the like, or a combination thereof. The adhesion layer 30 may be deposited using a suitable technique, such as CVD, PVD, ALD, the like, or a combination thereof. However, any suitable materials and any suitable methods of deposition may be utilized.

In FIG. 9, the routing layers 32 are deposited on the adhesion layer 30 to form the laser diode 34, in accordance with some embodiments. The laser diode 34 comprises the layers and structures formed on the substrate 10, as shown in FIG. 9. The routing layers 32 provide electrical routing for the laser diode 34 and allow for external electrical connections to be made to the laser diode 34. In some embodiments, the routing layers 32 comprise one or more layers of conductive materials such as aluminum, copper, aluminum copper alloy, another metal, the like, or a combination thereof. In some embodiments, the routing layers 32 are free of materials that can cause undesirable contamination during processing. For example, the routing layers 32 may be free of gold, other noble metals, or the like that can cause contamination or process defects. In some embodiments, the materials such as gold, other noble metals, or the like may be present only in the n-type contact 24 and/or the p-type contact 26 and may not be present in the routing layers 32. In this manner, contamination and process defects can be reduced while still allowing for quality electrical routing and/or electrical contacts to be formed.

The routing layers 32 may be formed using a suitable deposition process, such as CVD, PVD, ALD, plating, or a combination thereof. However, any suitable material and method of manufacture may be utilized. In an embodiment in which the routing layers 32 are plated, the routing layers 32 may be patterned during the deposition process. In other embodiments, the routing layers 32 may be patterned after deposition using, for example, a photolithographic masking and etching process. However, any suitable process may be utilized. In some embodiments, the routing layers 32 may have a thickness in the range of about 0.3 μm to about 5 μm, though other thicknesses are possible. In other embodiments, an optional additional adhesion layer (not shown) may be formed on the routing layers 32. In embodiments in which the additional adhesion layer is formed, the additional adhesion layer may be similar to the adhesion layer 30 and may be formed using similar materials or techniques.

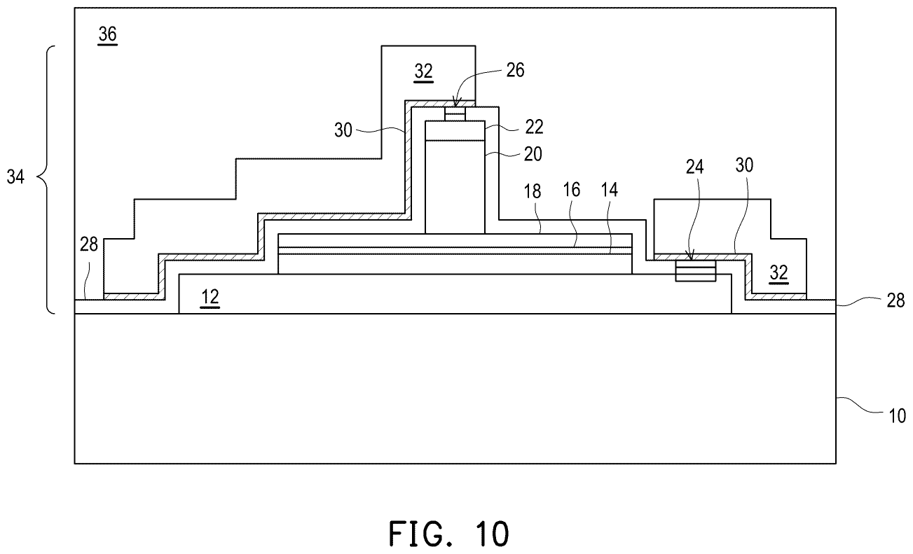

In FIG. 10, a passivation layer 36 is formed over the laser diode 34, in accordance with some embodiments. In an embodiment, the passivation layer 36 is a protective dielectric material such as silicon oxide, silicon nitride, silicon oxynitride, combinations of these, or the like. The passivation layer 36 may be deposited using a deposition process such as CVD, PVD, ALD, combinations of these, or the like. However, any suitable materials and methods may be used to form the passivation layer 36. In some embodiments, a planarization process may be performed to planarize the top surface of the passivation layer 36. The planarization process may comprise a chemical mechanical polish (CMP) process, a grinding process, or the like.

FIG. 11 illustrates a laser diode 34, in accordance with some embodiments. The structure shown in FIG. 11 is similar to the structure shown in FIG. 10, except that the n-type contact 24 and the p-type contact 26 comprise another number of conductive layers 25 and conductive layers 27, respectively. For example, the n-type contact 24 of FIG. 11 comprises four conductive layers 25, indicated as conductive layers 25A, 25B, 25C, and 25D, and the p-type contact 26 of FIG. 11 comprises three conductive layers 27, indicated as conductive layers 27A, 27B, and 27C. In some embodiments, the topmost conductive layer 25D of the n-type contact 24 and/or the topmost conductive layer 27C of the p-type contact 26 may comprise gold or the like. In some cases, forming a topmost conductive layer 25D/27C of gold can improve the conductive properties of the n-type contact 24 and the p-type contact 26. In some embodiments, a topmost conductive layer 25D/27C of gold is covered by the adhesion layer 30 and the routing layers 32 to reduce the chance of contamination.

FIGS. 12 through 16 illustrate additional intermediate steps in the formation of a laser die 50, in accordance with some embodiments. The process described for FIGS. 12-16 is shown using the laser diode 34 described for FIG. 10, but all other embodiments (e.g., the laser diode 34 of FIG. 11) described herein and variations thereof may be used. Accordingly, the process shown in FIGS. 12-16 follows from FIG. 10, in some embodiments.

In FIG. 12, the structure is flipped over and bonded to a support substrate 38, in accordance with some embodiments. For example, the passivation layer 36 may be bonded to the support substrate 38 using fusion bonding, direct bonding, dielectric-to-dielectric bonding, or the like. In some embodiments, the support substrate 38 may comprise silicon (e.g., a silicon wafer), a metal, a ceramic, or the like. In some embodiments, the bonding process may comprise performing an activation process on bonding surfaces of the passivation layer 36 and the support substrate 38 and then placing the passivation layer 36 and the support substrate 38 in physical contact to initiate the bonding process. A thermal process or the like may be used to strengthen the bond, in some cases. However, any other suitable attachment process, including using an adhesive, may be utilized.

In FIG. 13, the substrate 10 is removed, in accordance with some embodiments. After removal of the substrate 10, surfaces of the first contact layer 12 and/or the insulating layer 28 may be exposed. The substrate 10 may be removed using a CMP process, a grinding process, the like, or a combination thereof. In other embodiments, the substrate 10 may be removed using one or more etching processes, which may include wet etching processes and/or dry etching processes. The etching processes may be selective to the material of the substrate 10, and may stop on an etch stop layer (not shown) between the substrate 10 and the laser diode 34. In some embodiments, a planarization process may be performed after removal of the substrate 10. Other removal techniques are possible.

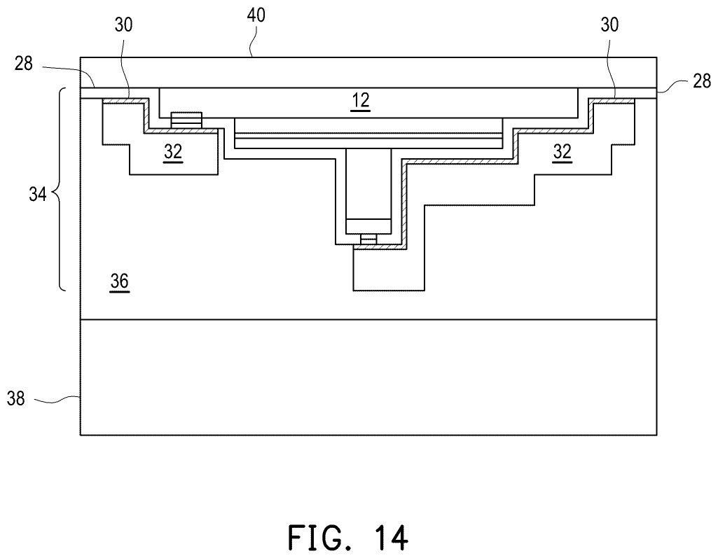

In FIG. 14, a dielectric layer 40 is deposited over the laser diode 34, in accordance with some embodiments. The dielectric layer 40 may comprise one or more layers of dielectric materials, such as silicon oxide, silicon nitride, silicon oxynitride, the like, or a combination thereof. In some embodiments, the dielectric layer 40 comprises a dielectric material suitable for dielectric-to-dielectric bonding. The dielectric layer 40 may be deposited using one or more processes, such as CVD, PVD, ALD, spin-on, or the like. Any suitable materials, deposition techniques, or number of layers may be used.

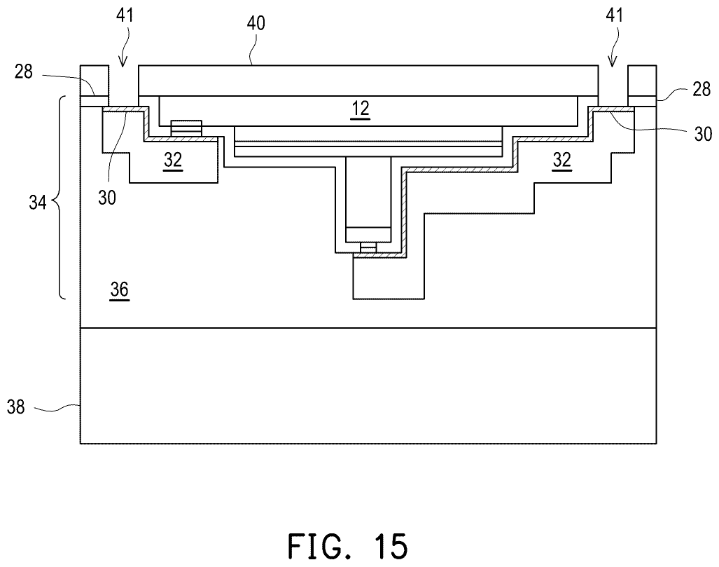

In FIG. 15, openings 41 are formed through the dielectric layer 40 and the insulating layer 28, in accordance with some embodiments. The openings 41 may extend through the dielectric layer 40 and the insulating layer 28 to expose the adhesion layer 30. In some embodiments, the openings 41 may extend through the adhesion layer 30 to expose the routing layers 32. The openings 41 may be formed using suitable photolithographic masking and etching techniques.

In FIG. 16, bonding pads 42 are formed in the openings 41 to form a laser die 50, in accordance with some embodiments. The bonding pads 42 are conductive features that make electrical contact to the routing layers 32 and allow for electrical connection between the laser die 50 and external structures. For example, at least one bonding pad 42 may be electrically connected to the n-type contact 24 and at least one bonding pad 42 may be electrically connected to the p-type contact 26. In some cases, the bonding pads 42 may comprise via portions that physically contact the n-type contact 24 and the p-type contact 26.

In some embodiments, the bonding pads 42 may be formed by depositing a conductive material in the openings 41. In an embodiment, the conductive material may comprise a barrier layer, a seed layer, a fill metal, or a combination thereof. For example, a barrier layer may first be blanket deposited over the dielectric layer 40 and within the openings 41. The barrier layer may comprise titanium, titanium nitride, tantalum, tantalum nitride, the like, or a combination thereof. The seed layer may be a conductive material such as copper and may be blanket deposited over the barrier layer using a suitable process, such as sputtering, evaporation, plasma-enhanced chemical vapor deposition (PECVD), or the like. The fill metal may be a conductive material such as copper, copper alloy, aluminum, or the like, and may be deposited using a suitable process, such as electroplating, electroless plating, or the like. The fill metal may fill or overfill the openings 41, in some embodiments. Once the fill metal has been deposited, excess material of the fill metal, the seed layer, and the barrier layer may be removed using, for example, a planarization process such as a CMP process or the like. After the planarization process, top surfaces of the dielectric layer 40 and the bonding pads 42 may be substantially level or coplanar, in some cases. Other materials or techniques are possible.

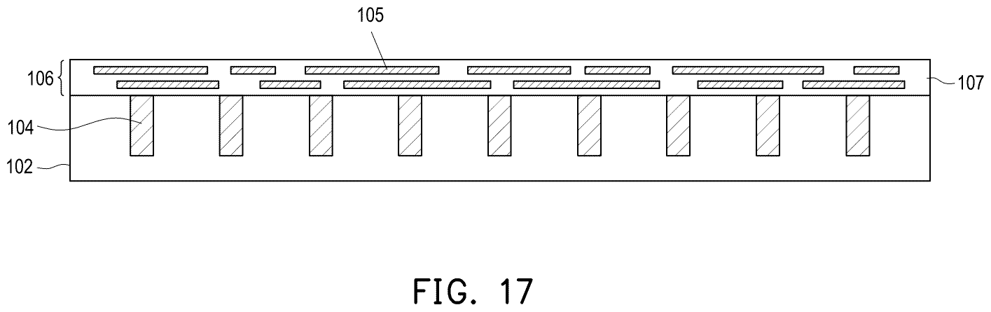

FIGS. 17 through 22 illustrate intermediate steps in the formation of a package 100, in accordance with some embodiments. In some embodiments, the package 100 comprises a laser die 50 and a semiconductor die 150 bonded to an interposer structure 101. In some embodiments, the laser die 50 provides optical power to waveguides 112 within the interposer structure 101. The package 100 described for FIGS. 17-22 is an example, and other configurations or arrangements are possible. For example, in other embodiments, more than one laser die 50 or more than one semiconductor die 150 may be bonded to the interposer structure 101. The interposer structure 101 or semiconductor die 150 may have other configurations, arrangements, or features than shown. All such variations are considered within the scope of the present disclosure. In some cases, the interposer structure 101 may be considered to be an optical interposer. In some cases, the package 100 may be considered to be an integrated chip, a photonic chip, an optical die, or the like.

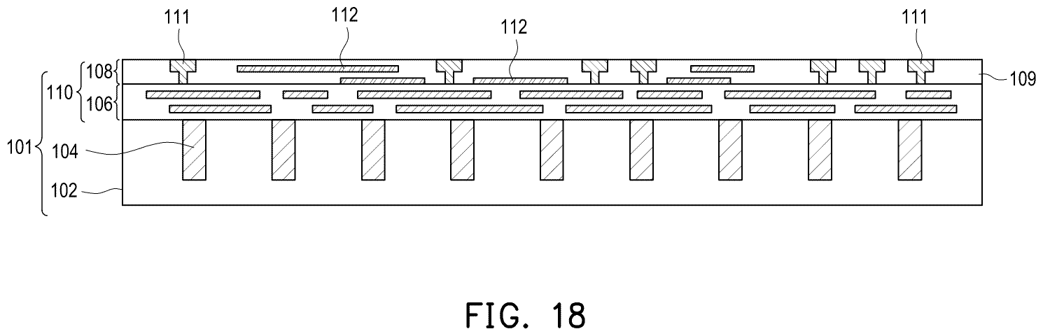

FIGS. 17 and 18 illustrate intermediate steps in the formation of an interposer structure 101, in accordance with some embodiments. The interposer structure 101 comprises interconnect layers 106 on a substrate 102, in accordance with some embodiments. The substrate 102 may be a wafer, such as a silicon wafer, in some embodiments. Other substrates, such as a silicon-on-insulator (SOI) substrate, a multi-layered substrate, or a gradient substrate may also be used. The substrate 102 may be doped (e.g., with a p-type or an n-type dopant) or undoped. In some embodiments, the semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 102 may be a dielectric material such as silicon oxide, glass, ceramic, plastic, polyimide, or any other suitable material that allows for structural support of overlying devices. In some embodiments, multiple interposer structures 101 may be formed on a single substrate 102 and then may be subsequently singulated into individual interposer structures 101 or individual packages 100. In some embodiments, active devices (e.g., transistors, diodes, or the like), passive devices (e.g. capacitors, resistors, or the like), integrated circuits, and/or the like may be formed in the substrate 102. The substrate 102 may be free of passive or active devices, in other embodiments.

In some embodiments, the interposer structure 101 comprises through vias 104 extending into the substrate 102. The through vias 104 are electrically connected to the interconnect layers 106. The through vias 104 may be formed, for example, by forming openings extending into the substrate 102. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the through vias 104. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the substrate 102 such that surfaces of the through vias 104 and the substrate 102 are level. The through vias 104 may protrude from the substrate 102 and into the interconnect layers 106, in other embodiments. Other materials or techniques are possible.

The interconnect layers 106 comprise one or more layers of conductive features 105 formed in one or more dielectric layers 107 (not individually illustrated), in some embodiments. The conductive features 105 may comprise conductive lines, conductive vias, conductive pads, metallization patterns, redistribution layers, or the like that provide electrical interconnections and electrical routing. In some embodiments, the interconnect layers 106 may have multiple layers of conductive features 105, but the precise number of layers of conductive features 105 may be dependent upon the design of the interposer structure 101. The conductive features 105 may be formed using any suitable techniques such as deposition, damascene, dual damascene, or the like. The conductive features 105 may include, for example, a metal or a metal alloy such as copper, silver, gold, tungsten, cobalt, ruthenium, aluminum, alloys thereof, combinations thereof, or the like. Other materials are possible.

Acceptable dielectric materials for the dielectric layers 107 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The dielectric layers 107 may be formed using any suitable techniques. In some embodiments, the interconnect layers 106 may have multiple dielectric layers 107, but the precise number of dielectric layers 107 may be dependent upon the design of the interposer structure 101.

In FIG. 18, interconnect layers 108 are formed over the interconnect layers 106 to form the interposer structure 101, in accordance with some embodiments. The interconnect layers 106 and the interconnect layers 108 may collectively considered to be an interconnect structure 110, in some cases. In some embodiments, the interconnect layers 108 comprise bonding pads 111 and waveguides 112 formed in one or more dielectric layers 109 (not individually illustrated). The interconnect layers 108 may also comprise conductive features similar to the conductive features 105, in some cases. The dielectric layers 109 may be similar to the dielectric layers 107, in some cases. In some embodiments, the topmost dielectric layer 109 is a bonding layer formed of a material suitable for dielectric-to-dielectric bonding.

In some embodiments, the bonding pads 111 are formed in the topmost dielectric layer 109 of the dielectric layers 109. The bonding pads 111 are electrically coupled to underlying conductive features, which may include conductive features 105. In some cases, the bonding pads 111 may also be considered conductive features of the interconnect layers 108. The bonding pads 111 may be formed using suitable techniques, such as deposition, damascene, dual damascene, or the like. The bonding pads 111 may include, for example, a metal or a metal alloy such as copper, aluminum, alloys thereof, combinations thereof, or the like. Other materials are possible. In some embodiments, a planarization process (e.g., a CMP process or grinding process) may be performed to level surfaces of the topmost dielectric layer 109 and the bonding pads 111.

The waveguides 112 may allow for the transmission of optical power and/or optical signals within the interposer structure 101. FIG. 18 shows two layers of waveguides 112 formed within the dielectric layers 109, but another number of layers of waveguides 112 may be formed in other embodiments. In some embodiments, a waveguide 112 may be optically coupled to an adjacent waveguide 112, to an overlying waveguide 112 of another layer, and/or to an underlying waveguide 112 of another layer. Waveguides 112 may be optically coupled using suitable techniques, such as using evanescent coupling, grating couplers, or other optical coupling techniques. The waveguides 112 may have a different configuration or arrangement than shown.

In some embodiments, a layer of waveguides 112 may be formed by depositing a waveguide material on a dielectric layer 109 and then patterning the waveguide material. In some embodiments, the waveguide material may be deposited on the dielectric layer 109 and thus the resulting waveguides 112 are formed on the dielectric layer 109. In other cases, the waveguide material is deposited on a previously deposited dielectric layer 109. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. The waveguide material may be deposited using a suitable technique, such as CVD, PVD, ALD, or the like. The waveguide material may then be patterned using suitable photolithographic masking and etching techniques to form a layer of waveguides 112. Another dielectric layer 109 may then be deposited over the waveguides 112. The steps of depositing a waveguide material, patterning the waveguide material to form a layer of waveguides 112, and then depositing a dielectric layer 109 over the layer of waveguides 112 may be repeated to form multiple layers of waveguides 112 within the interconnect layers 108.

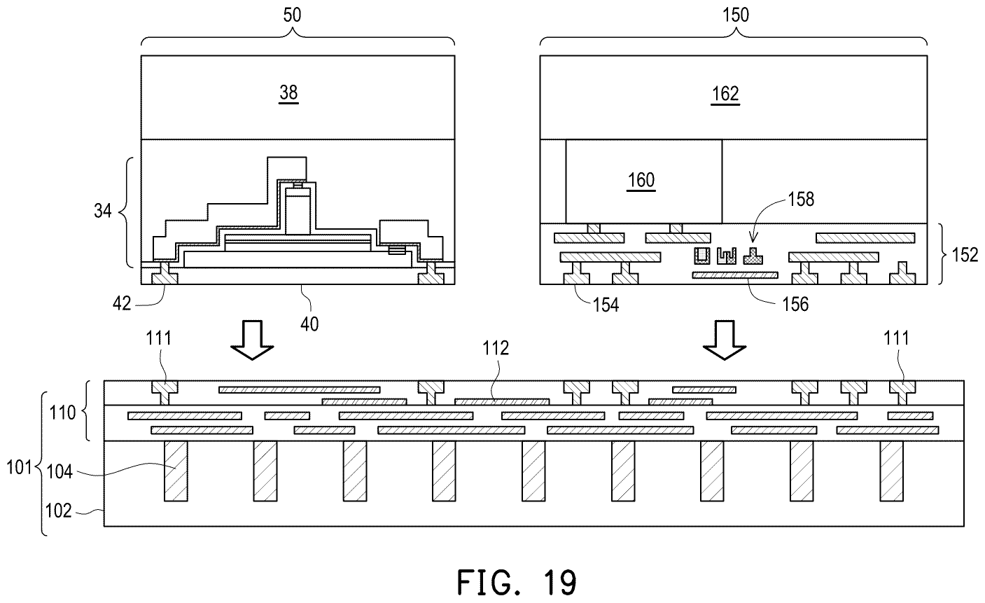

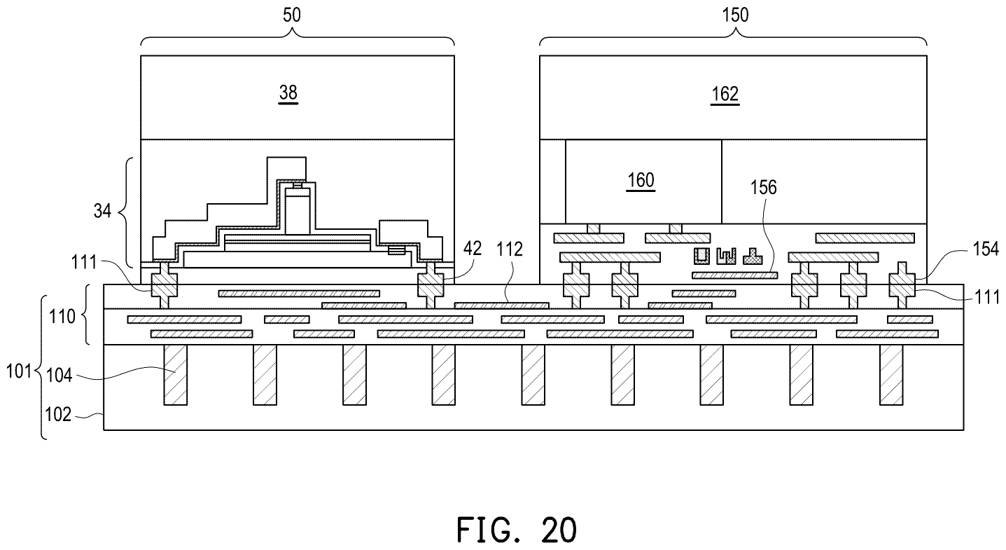

FIGS. 19 and 20 illustrate the bonding of a laser die 50 and a semiconductor die 150 to the interposer structure 101, in accordance with some embodiments. FIG. 19 illustrates the laser die 50 and semiconductor die 150 prior to bonding to the interposer structure 101, and FIG. 20 illustrates the laser die 50 and semiconductor die 150 after bonding to the interposer structure 101. The laser die 50 may be similar to the laser die 50 described previously for FIG. 16. In some embodiments, the laser die 50 and/or the semiconductor die 150 may have a thickness in the range of about 50 μm to about 700 μm, though other thicknesses are possible. The semiconductor die 150 shown and described is an illustrative example, and other dies, packages, components, or the like may be used in other embodiments.

The semiconductor die 150 may be a die, a chip, a system-on-chip (SoC) device, a system-on-integrated-circuit (SoIC) device, a package, a component, the like, or a combination thereof. In some cases, the semiconductor die 150 comprises an electronic die 160 connected to an interconnect structure 152. A support structure 162 may be over the electronic die 160 and may be similar to the support substrate 38 described previously, in some embodiments. For example, in some cases, the support structure 162 may be silicon or the like. The interconnect structure 152 may comprise a plurality of conductive features, waveguides 156, photonic components 158, and/or other features formed in dielectric layers. In some cases, the interconnect structure 152 may be considered a photonic integrated circuit (PIC) or the like. The interconnect structure 152 may include multiple layers of conductive features formed in multiple dielectric layers. The conductive features may include conductive lines, conductive vias, conductive pads, or the like, and may include bonding pads 154 formed in a bonding layer. The interconnect structure 152 may or may not include active devices.

In some embodiments, the photonic components 158 may include such devices or components as optical waveguides (e.g., ridge waveguides, rib waveguides, buried channel waveguides, diffused waveguides, etc.), couplers (e.g., grating couplers, edge couplers comprising a tip waveguide having a width in the range of about 1 nm to about 200 nm, etc.), directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. However, the photonic components 158 may comprise other devices, structures, or components than these examples. The photonic components 158 may be optically coupled to waveguides 156 of the interconnect structure 152. The waveguides 156 may be formed of a suitable material such as silicon, germanium, silicon nitride, a polymer, or the like.

In some embodiments, an electronic die 160 is connected to the interconnect structure 152 such that the electronic die 160 is electrically coupled to the interconnect structure 152. In other embodiments, multiple electronic dies 160 are connected to the interconnect structure 152, or an electronic die 160 may have other dimensions than shown. The electronic die 160 may be bonded to the interconnect structure 152 using, for example, fusion bonding or solder bumps.

The electronic die 160 may comprise, for example, a chip, a die, a system-on-chip (SoC) device, a system-on-integrated-circuit (SoIC) device, the like, or a combination thereof. For example, the electronic die 160 may include controllers, drivers, transimpedance amplifiers, transistors, other active devices, resistors, capacitors, other passive devices, the like, or combinations thereof. Accordingly, the electronic die 160 may be considered an electronic integrated circuit (EIC) or the like. In some embodiments, the integrated circuits may be configured to interface with the photonic components 158. For example, the integrated circuits may be configured to control the operation of the photonic components 158, to process electronic signals received from the photonic components 158, or the like. The integrated circuits may be configured to control high-frequency signaling of the photonic components 158 according to received electrical signals (digital or analog). In this manner, the electronic die 160 may process or transmit electrical signals based on received optical signals and/or may process or transmit optical signals based on received electrical signals.

In some embodiments, the electronic die 160 may provide Serializer/Deserializer (SerDes) functionality. In some embodiments, the electronic die 160 may comprise one or more processing devices, such as a Central Processing Unit (CPU or “xPU”), a Graphics Processing Unit (GPU), an Application-Specific Integrated Circuit (ASIC), a High-Performance Computing (HPC) die, a Micro Control Unit (MCU) die, a BaseBand (BB) die, an Application processor (AP) die, an Application-Specific Integrated Circuit (ASIC) die, a logic die, the like, or a combination thereof. The electronic die 160 may include one or more memory devices, which may be a volatile memory such as Dynamic Random-Access Memory (DRAM), Static Random-Access Memory (SRAM), High-Bandwidth Memory (HBM), another type of memory, or the like. Other types or configurations of electronic dies 160 are possible.

In FIG. 20, the laser die 50 and the semiconductor die 150 are bonded to the interposer structure 101, in accordance with some embodiments. For example, the bonding pads 42 of the laser die 50 and the bonding pads 154 of the semiconductor die 150 may be bonded to corresponding bonding pads 111 of the interconnect structure 110 using metal-to-metal bonding (e.g., fusion bonding, direct bonding, or the like). In some embodiments, bonding layers of the laser die 50 and/or the semiconductor die 150 are bonded to a bonding layer of the interconnect structure 110 using dielectric-to-dielectric bonding (e.g., oxide-to-oxide bonding, fusion bonding, direct bonding, or the like).

In some embodiments, the bonding process may be initiated by activating the bonding surfaces and/or bonding pads of the laser die 50, the semiconductor die 150, and/or the interconnect structure 110. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments. After the activation process, the laser die 50 and the semiconductor die 150 are aligned and placed into physical contact with the interconnect structure 110. The laser die 50, the semiconductor die 150, and the interposer structure 101 are then subjected to a thermal treatment and contact pressure to bond respective bonding layers together with dielectric-to-dielectric bonding and bond the corresponding bonding pads together with metal-to-metal bonding. In some embodiments, the resulting bonded structure is subsequently baked, annealed, pressed, or otherwise treated to strengthen or finalize the bond. This is an example, and other bonding processes are possible.

In some embodiments, after bonding, waveguides 112 of the interconnect structure 110 are optically coupled to the laser diode 34 of the laser die 50 and/or to waveguide(s) 156 of the semiconductor die 150. In this manner, optical power may be transmitted from the laser die 50 to waveguide(s) 112, and then may be transmitted from waveguide(s) 112 to the semiconductor die 150. In some embodiments, optical signals may be transmitted between waveguide(s) 112 of the interconnect structure 110 and waveguide(s) 156 of the semiconductor die 150. In this manner, optical communication within a package or between components thereof may be achieved.

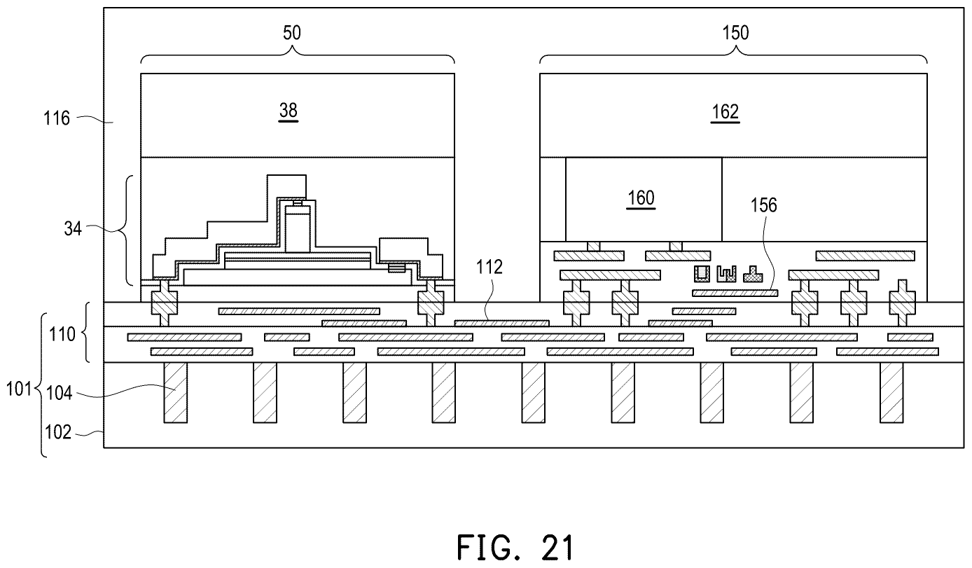

In FIG. 21, an encapsulant 116 is formed on and around the laser die 50 and the semiconductor die 150, in accordance with some embodiments. After formation, the encapsulant 116 encapsulates the laser die 50 and the semiconductor die 150. The encapsulant 116 may be a molding compound, an epoxy, a polymer, a composite material, a dielectric material, or the like. In some embodiments, the encapsulant 116 is applied by deposition, spin-on, compression molding, transfer molding, or the like. The encapsulant 116 may be formed over the interconnect structure 110 such that the laser die 50 and the semiconductor die 150 are buried or covered. The encapsulant 116 may be applied in liquid or semi-liquid form and then subsequently cured.

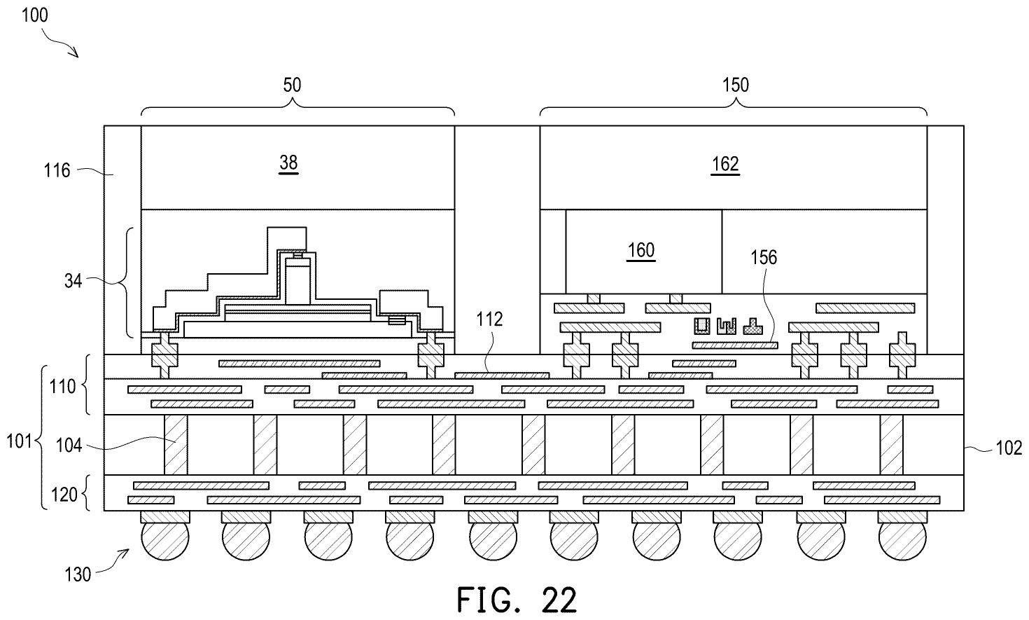

In FIG. 22, a planarization process is performed on the encapsulant 116 to expose the laser die 50 and the semiconductor die 150, in accordance with some embodiments. Top surfaces of the laser die 50, the semiconductor die 150, and the encapsulant 116 may be substantially level or coplanar (within process variations) after performing the planarization process. The planarization process may comprise, for example, a chemical-mechanical polish (CMP) process, a grinding process, an etching process, or the like. In other embodiments, a planarization process is not performed.

Further in FIG. 22, interconnect layers 120 are formed on the back side of the substrate 102 as part of the interposer structure 101, in accordance with some embodiments. In some embodiments, material is first removed from the back side of the substrate 102 to expose the through vias 104. The material of the substrate 102 may be removed using a CMP process, a grinding process, an etching process, the like, or a combination thereof. After removing the material of the substrate 102, surfaces of the through vias 104 and the substrate 102 may be substantially level or coplanar. After exposing the through vias 104, interconnect layers 120 are formed on the through vias 104 and on the back side of the substrate 102, in accordance with some embodiments. The interconnect layers 120 may be similar to the interconnect layers 106, and may be formed using similar materials or techniques. For example, the interconnect layers 120 may comprise one or more layers of conductive features formed in one or more dielectric layers.

In some embodiments, conductive connectors 130 are formed on the back side of the interposer structure 101 to form the package 100, in accordance with some embodiments. The conductive connectors 130 are physically and electrically connected to conductive features of the interconnect layers 120, and may be used to connect the package 100 to an external component or package substrate. The conductive connectors 2130 may comprise, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 130 may include a conductive material such as solder, copper, aluminum, gold, nickel, silver, palladium, tin, the like, or a combination thereof. In some embodiments, the conductive connectors 130 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 130 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, the conductive connectors 130 comprise under-bump metallizations (UBMs) formed on the interconnect layers 120.

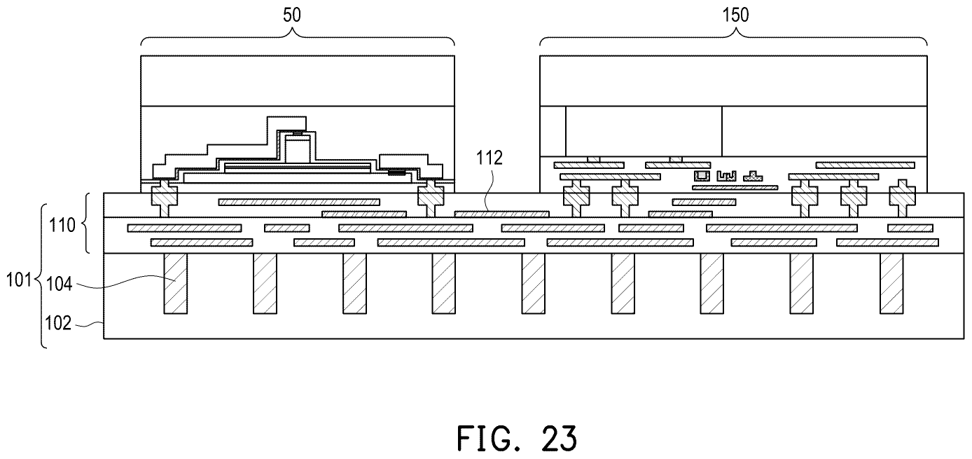

FIGS. 23 through 26 illustrate intermediate steps in the formation of a package 200, in accordance with some embodiments. The package 200 is similar to the package 100 described for FIG. 22, except that the laser die 50 and the semiconductor die 150 are thinner, and the package 200 includes a support structure 207. For example, in some embodiments, the laser die 50 and the semiconductor die 150 of the package 200 may have a thickness in the range of about 5 μm to about 50 μm, though other thicknesses are possible.

In FIG. 23, the laser die 50 and the semiconductor die 150 are attached to an interposer structure 101, in accordance with some embodiments. The interposer structure 101 may be similar to the interposer structure 101 described previously for FIG. 18. For example, the interposer structure 101 may include through vias 104 and an interconnect structure 110 that includes waveguides 112. The laser die 50 and the semiconductor die 150 may be bonded to the interposer structure 101 using fusion bonding (e.g., metal-to-metal bonding and dielectric-to-dielectric bonding), which may be similar to that described previously for FIG. 20. In this manner, the laser die 50 and semiconductor die 150 may be electrically and optically coupled to the interconnect structure 110 of the interposer structure 101.

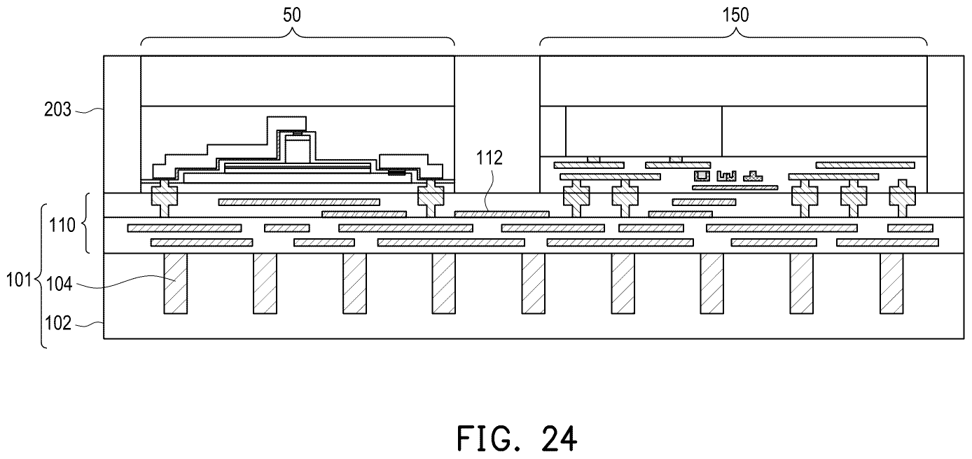

In FIG. 24, an encapsulant 203 is formed on and around the laser die 50 and the semiconductor die 150, in accordance with some embodiments. After formation, the encapsulant 203 encapsulates the laser die 50 and the semiconductor die 150. The encapsulant 203 may be similar to the encapsulant 116 described previously for FIG. 21. For example, the encapsulant 203 may be a molding compound, an epoxy, a polymer, a composite material, a dielectric material, an oxide (e.g., silicon oxide), or the like. In some embodiments, the encapsulant 203 is applied by deposition, spin-on, compression molding, transfer molding, or the like. The encapsulant 203 may be formed over the interconnect structure 110 such that the laser die 50 and the semiconductor die 150 are buried or covered. The encapsulant 203 may be applied in liquid or semi-liquid form and then subsequently cured.

Further in FIG. 24, a planarization process is performed on the encapsulant 203 to expose the laser die 50 and the semiconductor die 150, in accordance with some embodiments. Top surfaces of the laser die 50, the semiconductor die 150, and the encapsulant 203 may be substantially level or coplanar (within process variations) after performing the planarization process. In some cases, the planarization process may also remove upper portions of the laser die 50 and/or the semiconductor die 150. The planarization process may comprise, for example, a chemical-mechanical polish (CMP) process, a grinding process, an etching process, or the like. In other embodiments, a planarization process is not performed.

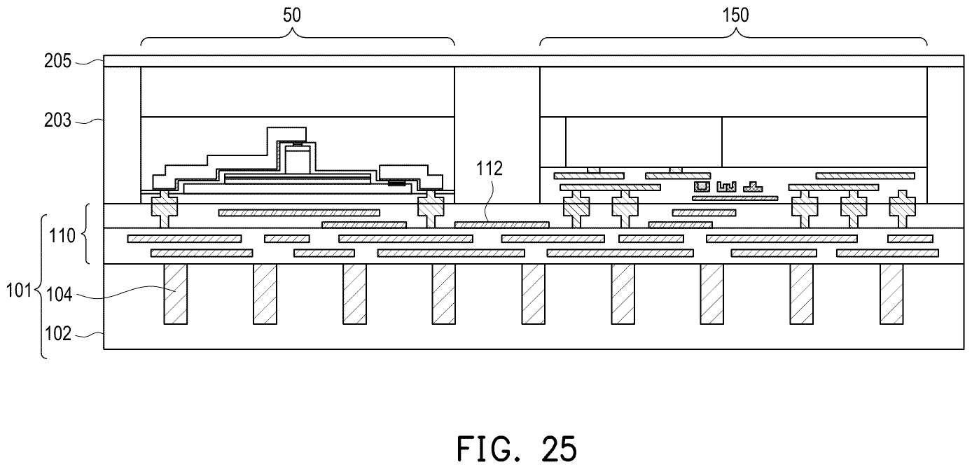

In FIG. 25, a bonding layer 205 is deposited over the encapsulant 203, the laser die 50, and the semiconductor die 150, in accordance with some embodiments. The bonding layer 205 may comprise one or more materials suitable for dielectric-to-dielectric bonding, such a silicon oxide, silicon oxynitride, or the like. The bonding layer 205 may be deposited using a suitable process, such as CVD, PVD, ALD, or the like.

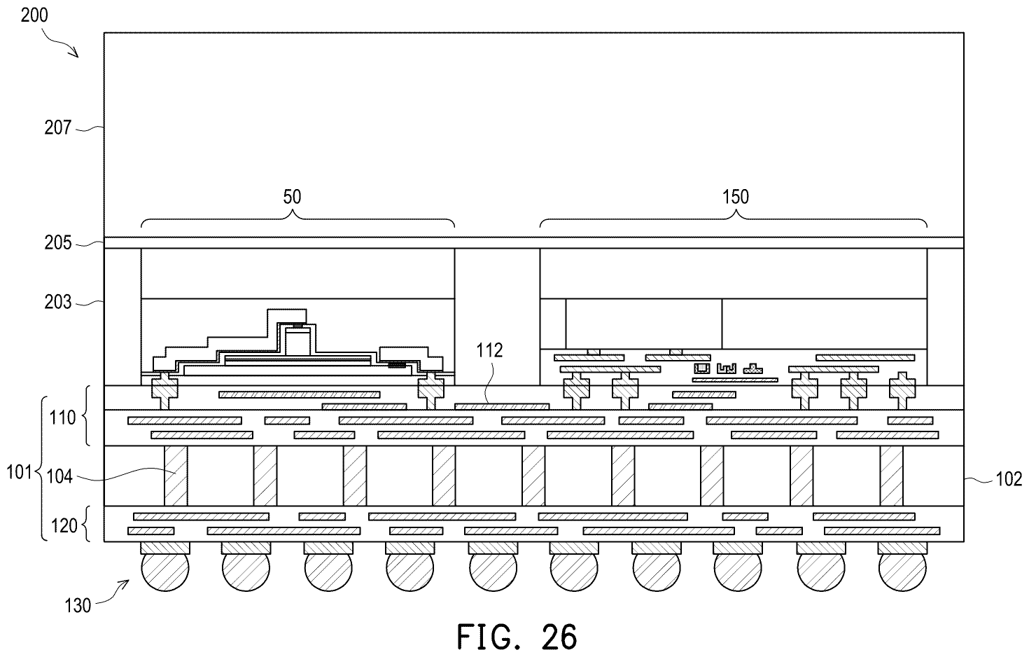

In FIG. 26, a support structure 207 is attached to the bonding layer 205 to form the package 200, in accordance with some embodiments. The support structure 207 may comprise one or more materials such as silicon, a dielectric (e.g., an oxide), metal, ceramic, plastic, the like, or a combination thereof. For example, the support structure 207 may be similar to the support substrate 38 or the support structure 162. In some embodiments, the support structure 207 is bonded to the bonding layer 205 using fusion bonding, such as dielectric-to-dielectric bonding.

Further in FIG. 26, interconnect layers 120 are formed on the back side of the substrate 102 as part of the interposer structure 101, in accordance with some embodiments. The interconnect layers 120 may be similar to the interconnect layers 120 described previously for FIG. 22. In some embodiments, the back side of the substrate 102 is thinned to expose the through vias 104 before forming the interconnect layers 120. The interconnect layers 120 may be similar to the interconnect layers 106, and may be formed using similar materials or techniques. For example, the interconnect layers 120 may comprise one or more layers of conductive features formed in one or more dielectric layers. In some embodiments, conductive connectors 130 are formed on the back side of the interposer structure 101 to form the package 200, in accordance with some embodiments. The conductive connectors 130 may be similar to those described previously. In some cases, forming a package 200 as described may allow for the incorporation of thinner components or may result in an overall thinner package.

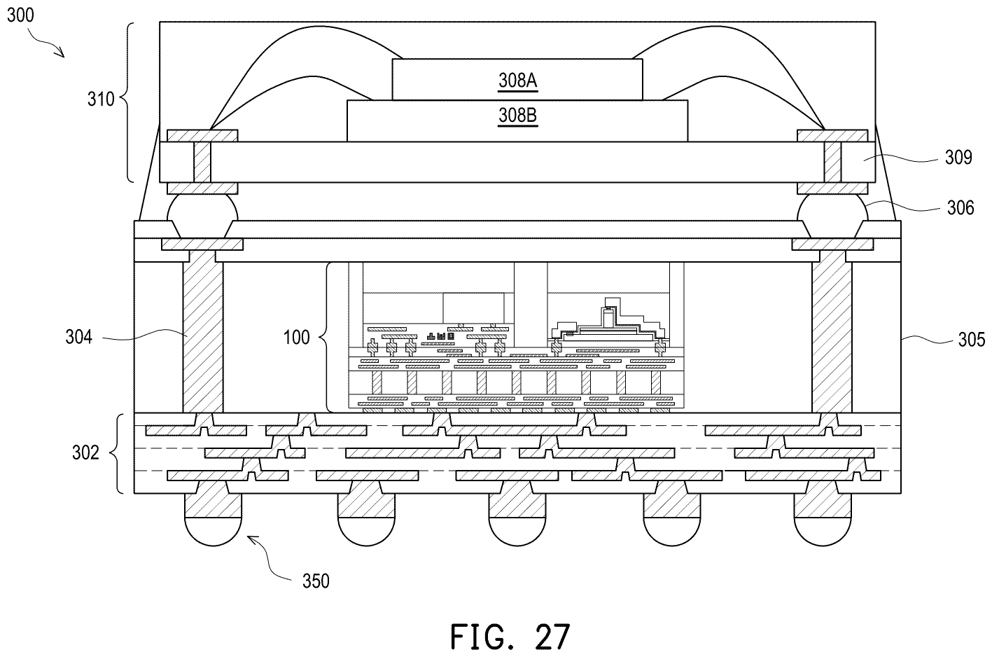

FIGS. 27, 28, and 29 illustrate example package structures 300, 400, and 500 that incorporate packages 100, in accordance with some embodiments. The embodiments of FIGS. 27-29 are shown with packages 100, but in other embodiments packages 200 may be used. The packages 100 shown in FIGS. 27-29 are similar to the package 100 shown in FIG. 22, except that conductive connectors 130 may be different than shown in FIG. 22. For example, the conductive connectors 130 may comprise conductive pads without solder bumps, in some cases. The embodiments shown in FIGS. 27-29 are intended as non-limiting examples, and other packages, package structures, or configurations thereof are possible.

FIG. 27 illustrates a package structure 300, in accordance with some embodiments. The package structure 300 may be similar to an Integrated Fan-Out (InFO) package or the like, in some cases. In the package structure 300, the package 100 is connected to a redistribution structure 302. For example, the interposer structure 101 of the package 100 may be electrically connected to the redistribution structure 302 by conductive connectors 130. The redistribution structure 302 includes metallization patterns formed in dielectric layers. The metallization patterns may also be referred to as redistribution layers or redistribution lines, and may comprise conductive lines, conductive vias, conductive pads, or the like. Conductive connectors 350 may be formed on the redistribution structure 302, which may be similar to the conductive connectors 130 described previously. The package 100 may be encapsulated by an encapsulant 305, and through vias 304 may be formed extending through the encapsulant to the redistribution structure 302. A package component 310 may be connected to the through vias 304 by conductive connectors 306, which may be solder balls or the like. The package component 310 may comprise one or more dies 308A-B on a substrate 309. The dies 308A-B may be electrically connected to the through vias 304. Other package components 310 are possible.

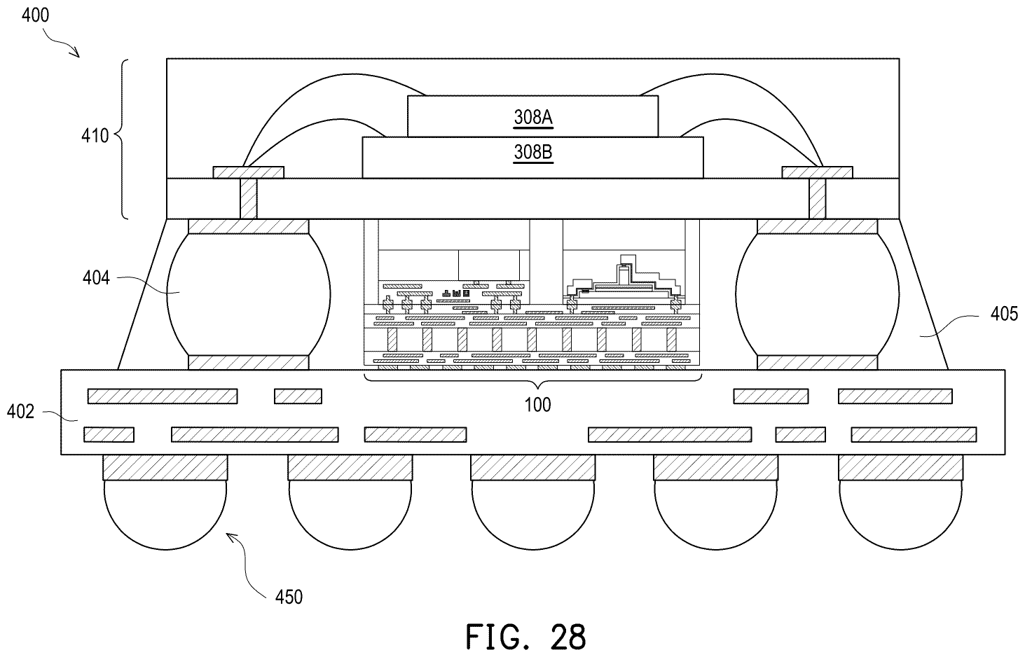

FIG. 28 illustrates a package structure 400, in accordance with some embodiments. The package structure 400 may be similar to a flip chip package or the like, in some cases. In the package structure 400, the package 100 is connected to a package substrate 402. For example, the interposer structure 101 of the package 100 may be electrically connected to the package substrate 402 by conductive connectors 130. The package substrate 402 may or may not include conductive routing, active devices, passive devices, or the like. Conductive connectors 450 may be formed on the package substrate 402, which may be similar to the conductive connectors 130 described previously. A package component 410 may be connected to the package substrate 402 by conductive connectors 404. The package component 410 may extend over the package 100, in some cases. The conductive connectors 404 may be solder balls or the like. An underfill 405 may surround the package 100 and the conductive connectors 404.

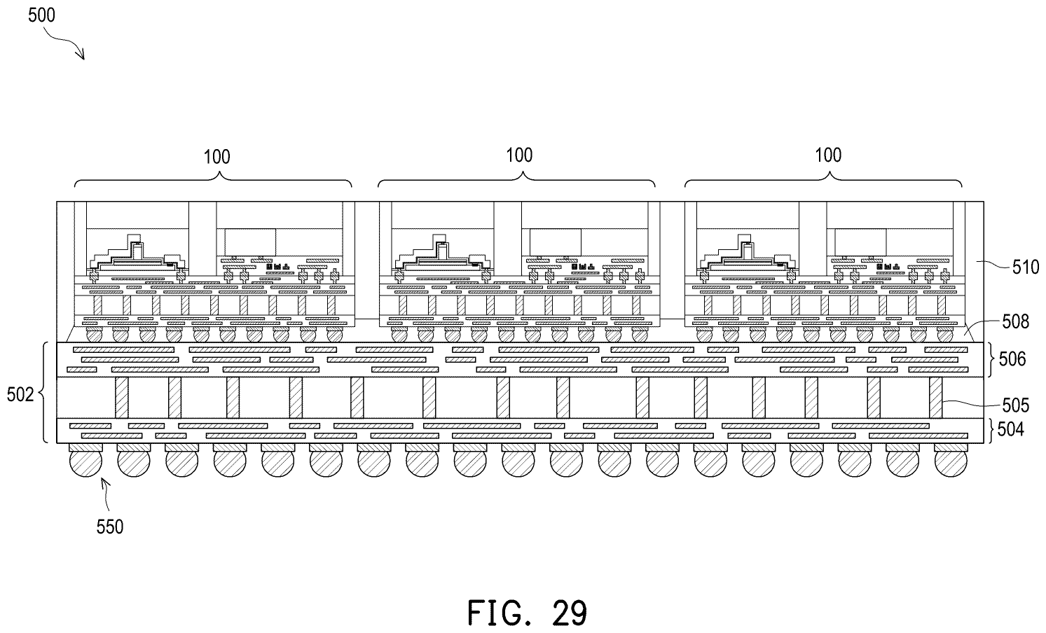

FIG. 29 illustrates a package structure 500, in accordance with some embodiments. The package structure 500 may be similar to a Chip-on-Wafer-on-Substrate (CoWoS) structure or the like, in some cases. In the package structure 500, multiple packages 100 are connected to an interposer 502. For example, the packages 100 may be electrically connected to the interposer 502 by conductive connectors 130. An underfill 508 may surround the conductive connectors 130, in some cases. The interposer 502 may comprise a back side interconnect structure 504 and a front side interconnect structure 506 on a substrate. Through vias 505 may extend through the substrate to connect the interconnect structures 504 and 506. Conductive connectors 550 may be formed on the back side interconnect structure 504, which may be similar to the conductive connectors 130 described previously. An encapsulant 510 may be formed over the interposer 502 and the packages 100, in some embodiments. These are examples, and other package structures incorporating packages 100, 200, or the like are possible.

The embodiments described herein can achieve advantages. Combining a laser die and a semiconductor die on an optical interposer can allow for optical and electrical signal communication within a package. The techniques described herein allow for the formation of a laser die that using processes and materials that are compatible with semiconductor fabrication. For example, the manufacturing of laser dies described herein allows for the use of noble metals or other materials in a manner that reduces the risk of contamination during subsequent processing of the laser dies into a package. The laser dies described herein utilize noble metals or other potential contaminants only for electrical contacts, and such materials are covered by electrical routing formed of more fab-compatible materials such as aluminum, copper, or the like. In this manner, the benefits of using noble metals in an electrical contact may be achieved without potentially contaminating exposure of the noble metals during subsequent processing. Accordingly, an optical package or the like may be formed without risk of contamination.

In some embodiments of the present disclosure, a method includes forming a laser diode structure including an active layer sandwiched between an n-type contact layer and a p-type contact layer; forming an n-type contact on the n-type contact layer, wherein the n-type contact includes a first noble metal; forming a p-type contact on the p-type contact layer, wherein the p-type contact includes a second noble metal; forming a conductive routing layer on the n-type contact and on the p-type contact, wherein the conductive routing layer is free of noble metals, wherein the conductive routing layer fully covers the n-type contact and the p-type contact; and forming a passivation layer over the conductive routing layer. In an embodiment, forming the n-type contact includes etching the n-type contact to form a recess and depositing the first noble metal into the recess. In an embodiment, the first noble metal is gold. In an embodiment, the second noble metal is platinum. In an embodiment, the conductive routing layer includes aluminum. In an embodiment, the method includes forming vias extending through the passivation layer to physically contact the conductive routing layer. In an embodiment, the method includes forming a conductive adhesion layer on the n-type contact and on the p-type contact, wherein the conductive routing layer is deposited on the conductive adhesion layer. In an embodiment, the method includes connecting the conductive routing layer to an optical interposer.

In some embodiments of the present disclosure, a method includes forming a first contact structure on a first contact layer of a laser diode, wherein the entire bottom surface of the first contact structure physically contacts a surface of the first contact layer; forming a second contact structure on a second contact layer of the laser diode, wherein the entire bottom surface of the second contact structure physically contacts a surface of the second contact layer; forming a first conductive layer on the first contact structure, wherein the first conductive layer is free of noble metals; and forming a second conductive layer on the second contact structure, wherein the second conductive layer is free of noble metals. In an embodiment, forming the first contact structure includes depositing a first stack of material layers, wherein at least one material layer is a noble metal. In an embodiment, the top material layer and the bottom material layer of the first stack are layers of gold. In an embodiment, forming the second contact structure includes depositing a second stack of material layers, wherein at least one material layer is a noble metal. In an embodiment, the first conductive layer includes copper. In an embodiment, the method includes recessing a portion of the first contact layer, wherein the first contact structure is formed in the recessed portion. In an embodiment, the method includes depositing a conductive adhesive layer on the first conductive layer and on the second conductive layer.

In some embodiments of the present disclosure, a device includes a laser die, which includes an n-type contact on an n-type contact layer; a multiple quantum well (MQW) layer over the n-type contact layer; a p-type contact on a p-type contact layer, wherein the p-type contact layer is over the MQW layer; and an aluminum routing layer on the n-type contact and on the p-type contact; an optical interposer bonded to the laser die, wherein the laser die is electrically and optically coupled to the optical interposer; and a semiconductor die bonded to the optical interposer, wherein the semiconductor die is electrically and optically coupled to the optical interposer. In an embodiment, the n-type contact includes a layer of gold, a layer of germanium, and a layer of nickel. In an embodiment, the p-type contact includes a layer of titanium and a layer of platinum. In an embodiment, a width of the p-type contact is less than a width of the p-type contact layer. In an embodiment, the n-type contact layer includes indium phosphide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a laser diode structure comprising an active layer sandwiched between an n-type contact layer and a p-type contact layer;
forming an n-type contact on the n-type contact layer, wherein forming the n-type contact comprises:
etching the n-type contact layer to form a recess; and
depositing gold into the recess;
forming a p-type contact on the p-type contact layer, wherein the p-type contact comprises a second noble metal;
forming a conductive routing layer on the n-type contact and on the p-type contact, wherein the conductive routing layer is free of noble metals, wherein the conductive routing layer fully covers the n-type contact and the p-type contact; and
forming a passivation layer over the conductive routing layer.
